(19) United States
(12) Patent Application Publication
(10) Pub. No.: US 2007/0256638 A1
(43) Pub. Date: Nov. 8, 2007

(54) Electrode plate for use in plasma processing and plasma processing system

(76) Inventors: Masanobu Honda, Nirasaki-Shi (JP); Shinichi Miyano, Nirasaki-Shi (JP); Naoki Matsumoto, Amagasaki-Shi (JP); Yutaka Matsui, Nirasaki-Shi (JP)

Correspondence Address: Smith, Gambrell & Russell, Suite 800, 1850 M Street, N.W., Washington, DC, 20036, US

(21) Appl. No.: 11/730,193

(22) Filed: Mar. 29, 2007

Related U.S. Application Data
(60) Provisional application No. 60/794,840, filed on Apr. 26, 2006.

(30) Foreign Application Priority Data
Mar. 30, 2006 (JP) 2006-095356

(51) Int. Cl. C23C 16/00; C23F 1/00

(52) U.S. Cl. 118/723 E

(57) ABSTRACT

The present invention is an electrode plate for use in plasma processing, to be placed in a plasma processing system so that it faces to a substrate to be subjected to plasma processing, characterized in that its resistivity is in the range of 0.01 mΩcm to 2 Ωcm.

### BACKGROUND OF THE INVENTION

1. Field of the Invention

The present invention relates to an electrode plate for use in plasma processing, and to a plasma processing system using the electrode plate.

1. Background Art

The parallel plate plasma processing system is known as a semiconductor production system. This plasma processing system comprises a processing vessel, and a lower electrode placed in this processing vessel also serves as a table for supporting a substrate. A gas-supply member in the shape of a shower head is positioned at the top of the processing vessel. The shower head has, at its underside (the part to be exposed to a processing atmosphere), an electrode plate into which a large number of gas-supply holes are bored, so that it functions as an upper electrode. Conductors, semiconductors, highly resistive materials, and the like are used for the electrode plate. For example, in cases where Si (silicon) is used for the electrode plate, usually used are those silicon materials whose resistivity (specific resistance) is approximately 2 Ωcm. Once plasma has been created in the processing vessel, the electrode plate is heated (the temperature of the electrode plate is raised) to about 400° C. by the heat of the plasma.

The temperature of the electrode plate at which plasma processing of substrates carried into the processing vessel is conducted right after restarting operation of the processing system after the operation has been suspended for a certain period and the electrode plate has been cooled is different from the temperature of the electrode plate at which plasma processing of substrates carried into the processing vessel is conducted after the electrode plate has been heated in continuous operation of the processing system. For example, the temperature of the electrode plate at which several substrates initially carried into the processing vessel right after starting operation of the processing system, or at the beginning of processing of a new lot of substrates, are processed is lower than the temperature of the electrode plate at which the succeeding substrates are processed.

The resistivity of the electrode plate depends on its temperature. Therefore, as the temperature of the electrode plate changes, the impedance of the electrode plate, relative to the plasma, changes. This change results in occurrence of drift in the electron density of the plasma. On the other hand, if plasma is created without carrying substrates, such as wafers, into the processing vessel, the surface of the table for supporting the substrate is damaged. A conventional measure taken to avoid this problem is that dummy wafers are carried into the processing vessel and are subjected to plasma processing until the temperature of the electrode plate becomes constant.

The diameters of wafers have been increased in recent years, and wafers with diameters of about 300 mm, for example, are presently used. To cope with the increase in wafer diameter, the diameters of dummy wafers have also been increased, and the costs of dummy wafers have thus gone up.

Japanese Laid-Open Patent Publication No. 92972/1999 (especially paragraph 0031) describes an electrode plate produced by a particular method, characterized in that its specific resistance (resistivity) is made 1 Ωcm or less. Japanese Laid-Open Patent Publication No. 7082/2001 (especially paragraph 0045) describes an electrode plate made of SiC, having a specified porosity and a specific resistance of 10 Ωcm or less. Japanese Laid-Open Patent Publication No. 223204/2001 (especially paragraph 0027) describes an electrode plate with a specified bore diameter, characterized in that its specific resistance is made 0.001 to 50 Ωcm.

However, all the above patent documents show no sign that the aforementioned problems in the prior art were examined, and they neither teach nor suggest any specific resistance value of the electrode plate that can be a solution to the above-described problems.

### SUMMARY OF THE INVENTION

In order to solve the above-described problems in the prior art, the present invention was accomplished. Accordingly, an object of the present invention is to provide an electrode plate for use in plasma processing, which undergoes only a little change in resistivity with temperature and can thus minimize occurrence of drift in electron density of plasma, thereby providing substrate-to-substrate uniformity in processing, and a plasma-processing system comprising the electrode plate.

The present invention is an electrode plate for use in plasma processing, to be placed in a plasma processing system so that it faces to a substrate to be subjected to plasma processing, wherein resistivity of the electrode plate is in a range of 0.01 mΩcm to 2 Ωcm.

According to the present invention, since the electrode plate for use in a plasma processing system is made so that its resistivity falls in the range of 0.01 mΩcm to 2 Ωcm, it undergoes only a little change in specific resistance when its temperature changes due to the heat incoming from the plasma, and drift that occurs in the electron density of the plasma due to a change in the specific resistance of the electrode plate is thus suppressed. Consequently, substrate-to-substrate uniformity in plasma processing can be attained. There is therefore no need to use dummy substrates until the temperature of the electrode plate becomes constant, so that the cost of plasma processing is kept low.

As will be described later, making the resistivity of the electrode plate of an upper electrode low is highly advantageous to a plasma processing system of the type that an RF generator for creating plasmas is connected to a lower electrode.

Preferably, the resistivity of the electrode plate is in a range of 0.01 to 1 mΩcm.

Further, it is preferred that the electrode plate be made up of Si or SiC doped with p- or n-type impurities.

The present invention is also a plasma processing system comprising a processing vessel containing a lower electrode on which a substrate will be placed, an RF generator for generating plasma, connected to the lower electrode, an upper electrode having an electrode plate, placed so that it faces to the lower electrode and that it is exposed to a processing atmosphere, a process-gas supply unit for supplying a process gas to the processing vessel, and a gas-discharging unit for evacuating the processing vessel to produce a vacuum, wherein the resistivity of the electrode plate is in a range of 0.01 mΩcm to 2 Ωcm.

According to the present invention, since the electrode plate to be used in the plasma processing system is made so that its resistivity falls in the range of 0.01 to 1 mΩcm, it undergoes only a little change in specific resistance when its temperature changes due to the heat incoming from the plasma, and drift that occurs in the electron density of the plasma due to a change in the specific resistance of the electrode plate is thus suppressed. Consequently, substrate-to-substrate uniformity in plasma processing can be attained. There is therefore no need to use dummy substrates until the temperature of the electrode- plate becomes constant, so that the cost of plasma processing is kept low. Further, since the RF generator for creating plasmas is connected to the lower electrode, making the resistivity of the electrode plate of the upper electrode low is highly advantageous.

Preferably, DC voltage is adapted to be applied to the electrode plate of the upper electrode.

Further, it is preferred that the resistivity of the electrode plate be in a range of 0.01 to 1 mΩcm.

Furthermore, it is preferred that the electrode plate be made up of Si or SiC doped with p- or n-type impurities.

### BRIEF DESCRIPTION OF THE DRAWINGS

In the drawings,

FIG. 1 is a diagrammatical, longitudinal section of an etching system, a plasma processing system according to an embodiment of the present invention,

FIG. 2A is a table showing a relationship between specific resistance and temperature, and FIG. 2B is a graph showing the same,

FIG. 3 is a view illustrating skin depth on a plasma surface,

FIG. 4 is a graph showing a relationship between skin depth and frequency,

FIGS. 5A and 5B are graphs showing changes in the electron density of plasma with processing time,

FIG. 6 is a view illustrating the film composition of the wafer used in Example 2,

FIGS. 7A to 7D are graphs showing rates of etching the films formed on a wafer, shown in FIG. 6, and

FIG. 8 is a graph showing how ion energy exerted to the processing chamber changes with DC voltage applied to the upper electrode in Example 3.

### BEST MODE FOR CARRYING OUT THE INVENTION

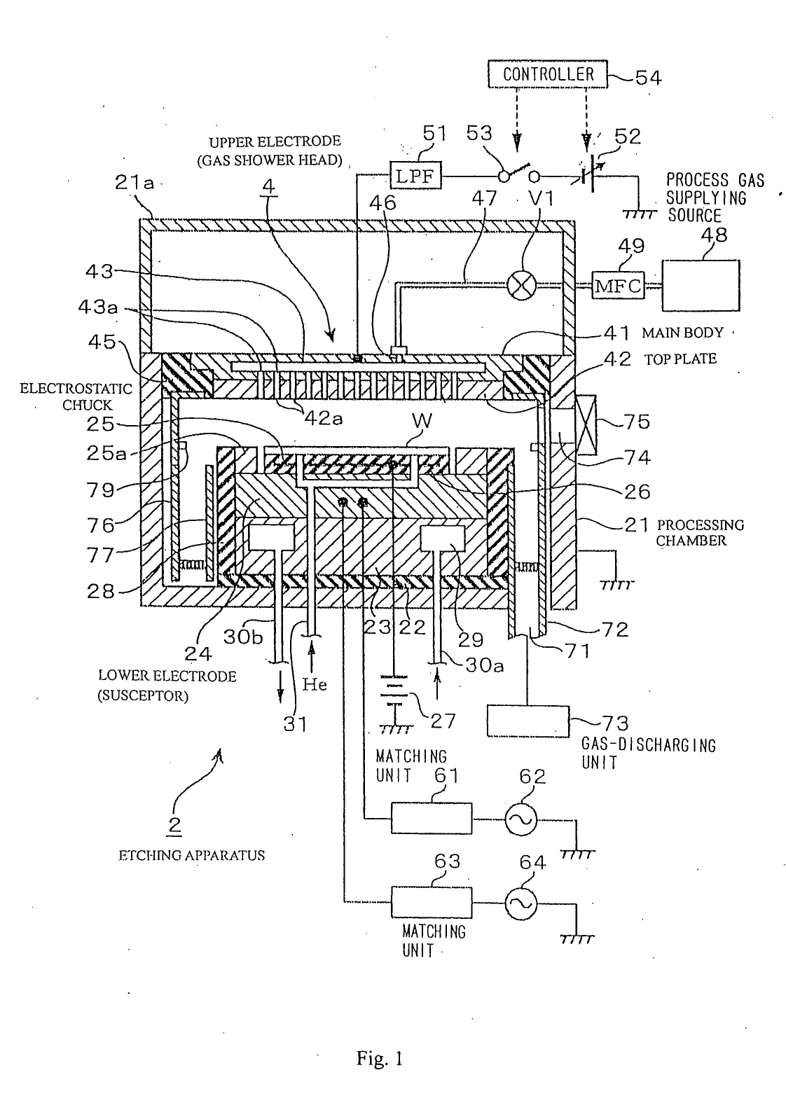

A plasma etching system, an embodiment of a plasma processing system according to the present invention, will be described hereinafter with reference to FIG. 1. The etching system 2 of this embodiment is a parallel plate plasma etching system of capacitive coupling type.

As shown in FIG. 1, a supporting member 23 is positioned at the bottom of a processing chamber 21, a processing vessel, via an insulating plate 22 made of ceramics or the like. On this supporting member 23 is positioned a susceptor 24 made of aluminum or the like. The susceptor 24 constitutes a lower electrode. On top of the susceptor 24, an electrostatic chuck 25 for holding a wafer W by way of electrostatic adsorption is positioned at the center. The structure of the electrostatic chuck 25 of this embodiment is that an electrode 26 made of an electrically conductive film is sandwiched between a pair of insulating layers. To the electrode 26, a DC power supply 27 is electrically connected.

In order to enhance uniformity in etching, an electrically conductive focus ring (correction ring) 25a made of silicon or the like is put on the susceptor 24 around the electrostatic chuck 25. A cylindrical inner wall member 28 made of quartz or the like is positioned so that it surrounds both the susceptor 24 and the supporting member 23.

Inside the supporting member 23 is a cooling medium chamber 29 made in the circumferential direction, for example. To this cooling medium chamber 29, a cooling medium, such as cooling water, controlled to a predetermined temperature, is circularly supplied from a chiller unit, not shown in the figure, located outside the processing system, via pipes 30a and 30b. By making use of the temperature of the cooling medium, it is possible to control the temperature at which a wafer W on the susceptor 24 is processed. A heat transfer gas, such as He gas, is supplied from a heat-transfer-gas-supply mechanism, not shown in the figure, to the space between the top surface of the electrostatic chuck 25 and the back surface of the wafer W, via a gas-supply line 31.

Above the susceptor 24 serving as a lower electrode, an upper electrode 4 is positioned so that it faces to the susceptor 24. The space between the upper electrode 4 and the lower electrode (susceptor) 24 is one in which plasma is created. The upper electrode 4 is composed of a body 41 and a top plate 42 serving as an electrode plate. It is attached to the top of the processing chamber 21 with an insulating shield 45. The body 41 is made of an electrically conductive material, such as anodized aluminum. The lower part of the body 41 is made so that it can detachably hold the top plate 42.

There is a gas-diffusing chamber 43 in the body 41. From this gas-diffusing chamber 43, a large number of gas-flow holes 43a, arranged uniformly, extend downwardly, for example. In the top plate 42, gas-feed holes 42a, through-holes extending in the direction of thickness, are present. The gas-flow holes 43a and the gas-feed holes 42a are arranged so that they meet each other completely.

A process gas supplied to the gas-diffusing chamber 43 is diffused through the gas-flow holes 43a and the gas-feed holes 42a into the processing chamber 21, just like the gas showers down from the top plate 42. Namely, the upper electrode 4 is made so that it functions as a gas shower head. The body 41 may have, for example, a pipe, not shown in the figure, in which a cooling liquid circulates. For example, this pipe is laid above the body 41 to cool the upper electrode 4 during etching processing.

The top plate 42 is made of a conductor or a semiconductor, such as Si, SiC, or carbon, doped with B (boron) or the like so that its specific resistance at normal temperatures (usually at 25° C.) falls in the range of 0.01 mΩcm (1×10⁻⁵ Ωcm) to 2 Ωcm. More preferably, the top plate 42 is made so that its specific resistance at normal temperatures (usually at 25° C.) falls in the range of 0.01 to 1 mΩcm. The reason why the top plate 42 is made so that its specific resistance falls in the above range will be described later in detail.

The thickness of the top plate 42 of this embodiment is approximately 10 mm. The preferred thickness of the top plate 42 is from 3 to 15 mm. A top plate 42 whose thickness is less than 3 mm is poor in mechanical strength, so that it can break or warp due to the heat of the plasma. On the other hand, a top plate 42 with a thickness of more than 15 mm requires increased production cost, so that such a great thickness is unfavorable.

The body 41 has a gas inlet 46 through which a process gas flows into the gas-diffusing chamber 43. To this gas inlet 46 is connected a gas-supply line 47, and to the gas-supply line 47, a process-gas-supplying source 48. A mass flow controller (MFC) 49 and an on-off valve V1 are connected to the gas-supply line 47, the former being on the upstream side of the latter. The process-gas-supplying source 48 supplies, as a process gas for etching, a fluorocarbon gas (CₓF_{y}), such as C₄F₈ gas, to the gas-diffusing chamber 43 via the gas-supply line 47. The process gas then flows into the processing chamber 21. Namely, the gas-supply line 47, the process-gas-supplying source 48, and the upper electrode 4 constitute a process-gas-supplying unit.

A variable DC power supply 52 is electrically connected to the upper electrode 4 via a low-pass filter (LPF) 51. This variable DC power supply 52 can be switched on or off by an on-off switch 53. A controller 54 controls the electric current and voltage of the variable DC power supply 52 and on/off of the on-off switch 53.

As will be described later, when creating plasma in the processing space by applying radio-frequency power, generated by first and second RF generators 62, 64, to the lower electrode 24, the controller 54 turns the switch 53 on to apply predetermined DC minus voltage to the upper electrode 4.

A cylindrical grounding conductor 21a is placed above the upper electrode 4 in such a manner that it extends from the top end of the sidewall of the processing chamber 21. This cylindrical grounding conductor 21a is closed at its top with a ceiling wall.

The first RF generator 62 is electrically connected, via a matching unit 61, to the susceptor 24 serving as a lower electrode. The second RF generator 64 is also connected to the susceptor 24 via a matching unit 63. The first RF generator 62 serves to create plasma between the upper electrode 4 and the lower electrode 24 by generating radio-frequency power with a frequency of 27 MHz or more, e.g., 40 MHz. The second RF generator 64 serves to let the wafer W, held by the electrostatic chuck, attract the activated ion species by generating radio-frequency power with a frequency of 13.56 MHz or less, e.g., 2 MHz.

The processing chamber 21 has an exhaust port 71 at its bottom. A gas-discharging unit 73, a means for exhausting the processing chamber 21, is connected to the exhaust port 71 via an exhaust pipe 72. The gas-discharging unit 73 has a vacuum pump, for example. By means of this gas-discharging unit 73, the processing chamber 21 can be evacuated to produce a desired degree of vacuum. The processing chamber 21 has, in its sidewall, an opening 74 through which a wafer W is carried into and out of the processing chamber 21. This opening 74 can be opened or closed by a gate valve 75.

In FIG. 1, reference numerals 76, 77 denote deposit shields. The deposit shield 76 is positioned along the inner wall of the processing chamber 21 and serves to protect the inner wall surface from deposition of by-products of etching (deposits). The deposit shield 76 is detachably attached to the inner wall surface. This deposit shield 76 has an electrically conductive member (GND block) 79 grounded in terms of direct current, this member 79 and the wafer W being at almost the same level. The electrically conductive member 79 prevents abnormal discharge.

The reason why the top plate 42 is made so that its resistivity falls in the above-described range will now be described in detail. In the case where plasma is created in the processing chamber 21 by applying radio-frequency power, generated by the RF generator, to the lower electrode 24, the top plate 42 is heated to a maximum of about 400° C., for example, due to the heat incoming from the plasma, unless it is cooled. The upper electrode 4 may have a cooling mechanism, as mentioned previously. However, since the quantity of the heat incoming from the plasma is so large that it is not easy to maintain the temperature of the upper electrode 4 constant during plasma processing. The temperature of the top plate 42, which has been kept at about 30 to 80° C. before conducting processing, gradually rises as the processing of wafers W carried into the processing chamber 21 progresses and finally becomes constant after reaching about 200° C., for example.

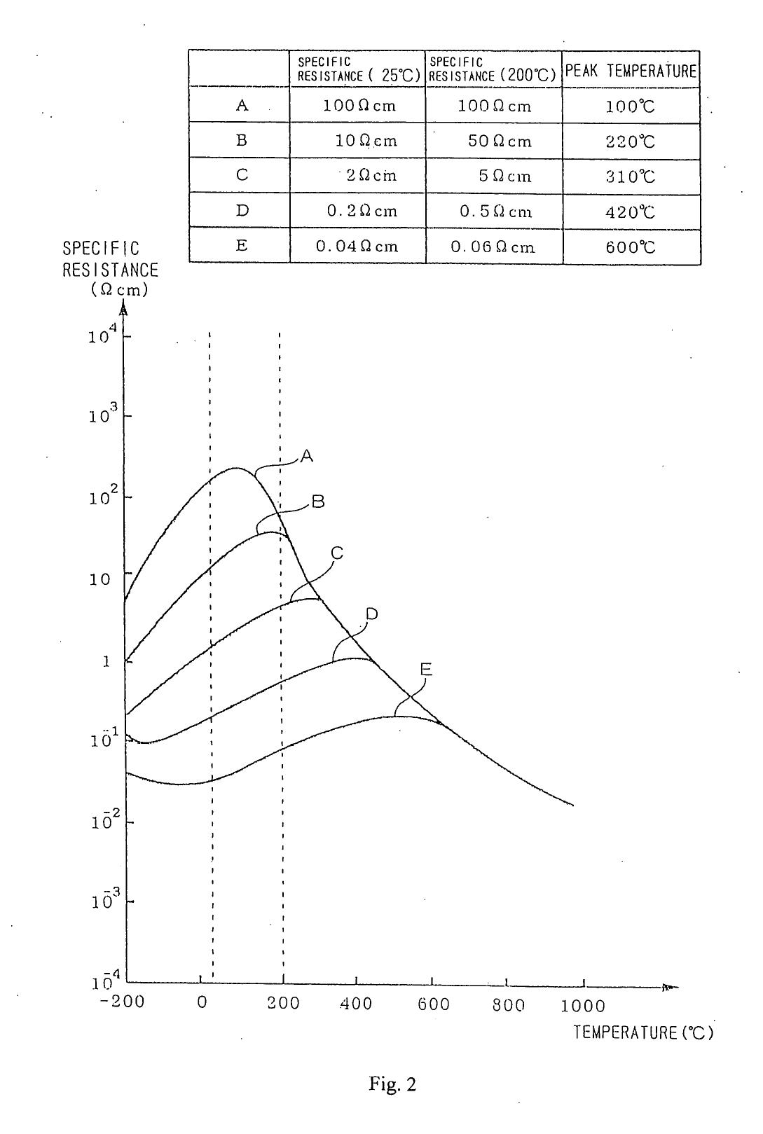

FIGS. 2A and 2B show how Samples A to E change in specific resistance with temperature, the samples being wafers made with Si (silicon) that has been doped with different amounts of B (boron) so that they have different specific resistance values at normal temperatures. The graph shown in FIG. 2B is the one shown in 17c on page 424 of Landolt-Boernstein. In this graph, it is clear that the specific resistance of the top plate 42 depends on its temperature. As the top plate 42 changes in specific resistance with its temperature, its impedance relative to the plasma varies, so that drift occurs in the electron density of the plasma. Further, as shown in the table in FIG. 2A and the graph in FIG. 2B that corresponds to the table, Samples A to E have maximum specific resistance values at different certain temperatures (peak temperatures=points of inflection). If the temperature of the top plate 42 reaches such a peak temperature in the course of processing, there is the possibility that wafer-to-wafer uniformity in processing will not be attained at around the peak temperature.

However, as the table in FIG. 2A and the graph in FIG. 2B show, a sample whose specific resistance at normal temperatures is lower undergoes a smaller change in specific resistance at temperatures between normal temperatures and 200° C. and has a peak temperature on the higher-temperature side. It is also understood that by making the top plate 42 so that its specific resistance at normal temperatures is 2 Ωcm or less, the change in the specific resistance of the top plate 42 can be suppressed to such an extent that the change in the electron density of the plasma scarcely affects the uniformity in processing in a wafer plane when the temperature of the top plate 42 is in the range of normal temperatures to 200° C. Further, the peak temperature at which the specific resistance of this top plate 42 reaches a maximum is not in the above-described range of processing temperature, which is preferable. It is more preferable to make the top plate 42 so that its specific resistance at normal temperatures is 0.2 Ωcm or less because the change in the specific resistance of such a top plate 42 with its temperature is smaller.

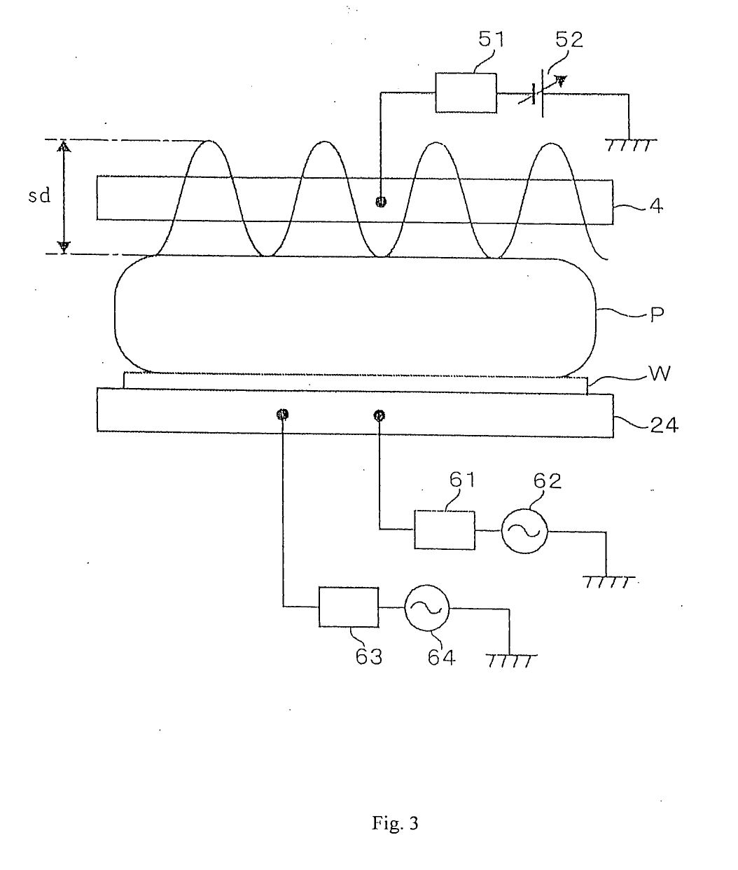

FIG. 3 is a diagrammatic view illustrating the state of plasma P created in the processing chamber 21 when processing wafers W. It is known that if a conductor or semiconductor is present around the plasma created, such an electrical field is created as to propagate radio-frequency waves from the plasma surface to the conductor or semiconductor side. Namely, as shown in FIG. 3, an electrical field in which radio-frequency waves are propagated is created above the plasma P created in the processing chamber 21. The distance sd from the surface of the plasma P to the farthest point at which the radio-frequency waves can arrive is called skin depth. The skin depth sd (m) is given by the following equation:
sd=√((ρ/πfu))
where ρ (Ωm) is the specific resistance (resistivity) of the top plate 42, f (Hz) is the frequency, and u is the magnetic permeability of the top plate 42.

When the skin depth sd is large, the radio-frequency waves permeate through the top plate 42 and enter the area above the upper electrode 4. In the area above the upper electrode 4, a pipe for a cooling liquid for cooling the upper electrode 4 and some other pipes for various gases are laid asymmetrically relative to the center of the wafer W, as mentioned previously. Namely, the area above the upper electrode 4 is not isotropic to the radio-frequency waves. Therefore, the radio-frequency waves that have entered the area above the upper electrode 4 are disturbed by the pipe for a cooling liquid and other gas pipes and become turbulent. Owing to this turbulence, the electron density of the plasma in the lower, circumferential layer part of the radio-frequency waves becomes non-uniform, and the uniformity in processing in a plane of the wafer W gets worse.

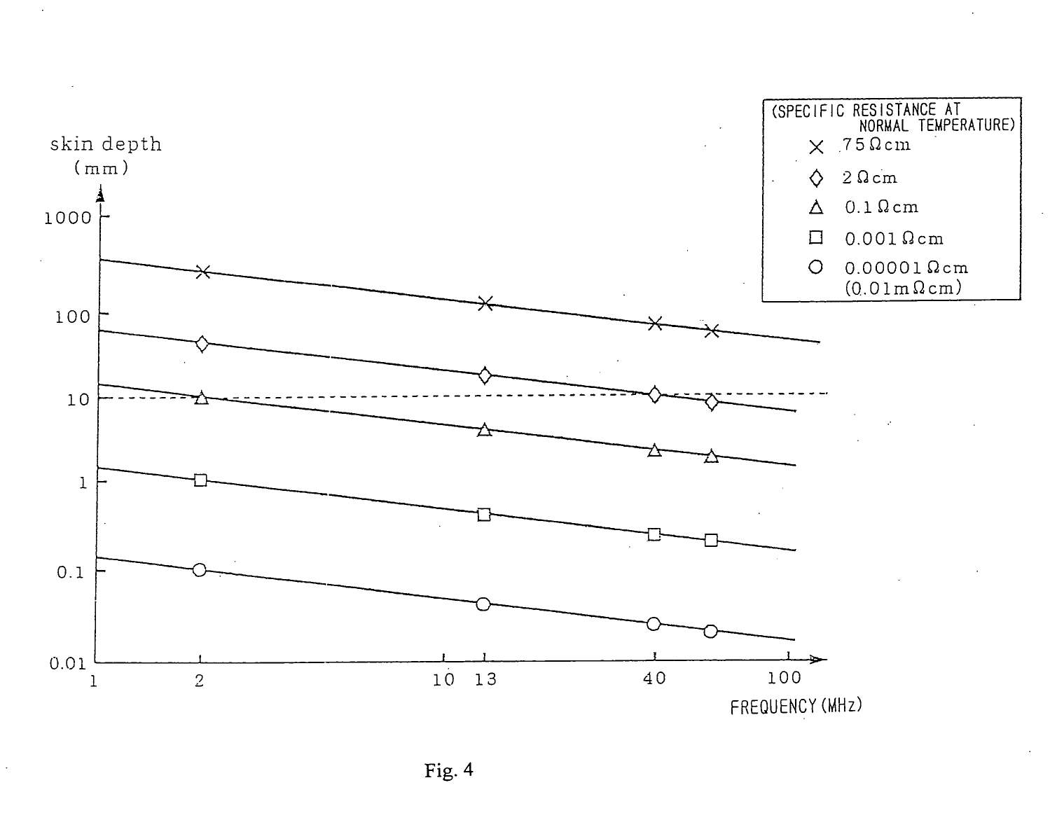

FIG. 4 is a graph showing how the skin depth sd changes according to the above equation. In this graph, the unit of the skin depth sd plotted vertically is mm, and that of the frequency plotted horizontally, MHz. It is understood from the graph that when the specific resistance of the top plate 42 is 0.1 Ωcm, and if radio-frequency power with a frequency of 40 MHz and that with a frequency of 2 MHz are applied to the lower electrode 24, as mentioned previously, the skin depths sd corresponding to the frequencies are several millimeters and about 10 mm, respectively. On the other hand, the thickness of the top plate 42 is about 10 mm, as mentioned before. Conceptually speaking, therefore, the constituent parts present in the area above the upper electrode 4 cannot be viewed from the plasma side. This means that since the constituent parts present in the area above the upper electrode 4 never disturb the electrical field, the distribution of plasma densities in a horizontal plane never becomes non-uniform.

On the other hand, when the skin depth sd is too small, the irregularities in micrometers, present in the surface of the top plate 42, can be seen from the plasma side (these irregularities disturb the electrical field), so that the electron density of the plasma becomes non-uniform. It is therefore preferable to control the skin depth sd to more than 10 mm (0.01 mm) for the frequency range of 1 to 100 MHz, which is usually used for plasma processing equipment. For the above-described reasons, the top plate 42 should be made so that its specific resistance at normal temperatures falls in the aforementioned range.

To conduct etching processing in the etching system 2 having the above-described structure, the gate valve 75 is first opened, and a wafer W to be etched is carried into the processing chamber 21 through the hole 74 and is placed on the susceptor 24. A process gas, such as a fluorocarbon gas or O₂ gas, is supplied from the process-gas-supply source 48 to the gas-diffusing chamber 43 at a predetermined flow rate. This process gas is then supplied to the processing chamber 21 via the gas-flow holes 43a and the gas-feed holes 42a, while exhausting the processing chamber 21 by the gas-discharging unit 73. The inner pressure of the processing chamber 21 is thus controlled to a preset pressure of 0.1 to 150 Pa, for example.

After the processing chamber 21 has been filled with the etching gas in the above-described manner, predetermined radio-frequency power for creating plasmas, generated by the first RF generator 62, is applied to the susceptor 24, a lower electrode. Predetermined radio-frequency power for attracting ions, generated by the second RF generator 64, is also applied to the susceptor 24. Predetermined DC voltage is applied to the upper electrode 4 by the variable DC power supply 52. Moreover, DC voltage for the electrostatic chuck is applied to the electrostatic chuck electrode by the DC power supply 27, thereby fixing the wafer W on the susceptor 24.

The process gas ejected from the gas-ejection holes in the top plate 42 of the upper electrode 4 becomes plasma in the glow discharge caused by the radio-frequency power between the upper electrode 4 and the susceptor 24 serving as a lower electrode. Radicals and ions in this plasma act to etch the wafer W surface to be processed.

In the above-described plasma etching system 2, since the top plate 42 is made so that its specific resistance falls in the range of 0.01 mΩcm to 2 Ωcm, it undergoes only a little change in specific resistance due to the heat incoming from the plasma (see FIG. 2B). Consequently, only a very little drift occurs in the electron density of the plasma.

More specifically, the above-described plasma etching system 2 brings about the following effects. Since the top plate 42 is cold at the time when the operation of the system is started or when the operation of the system is restarted after suspending it for a certain period (e.g., at the beginning of processing of a new lot of wafers), its temperature gradually rises while several wafers W initially carried into the processing chamber are processed because the incoming of the heat from the plasma and the outgoing of the heat cannot be balanced. This means that the initial several wafers W are processed while the temperature of the top plate 42 is still unsteady. In this embodiment, however, since a material whose specific resistance at normal temperatures falls in the range of 0.01 mΩcm to 2 Ωcm is used for the top plate 42, the change in the specific resistance of the top plate 42 with temperature is small. Therefore, the change in the electron density of the plasma in the course of processing wafers W is small, which leads to wafer-to-wafer uniformity in processing. Consequently, even if product wafers are processed from the beginning of processing of a new lot of wafers, yields are not affected adversely. Further, this operation can drastically reduce production cost, when compared with the operation using dummy wafers.

Since radio-frequency waves propagate along the surface of the electrode plate, the electric potential of the plasma tends to be higher at its center portion than at its outer edge portion. Therefore, in the case where an RF generator is connected to the upper electrode, a layout of the area above the upper electrode plate is usually devised to erase the above-described tendency. However, if the resistivity of the electrode plate (upper electrode plate) is made low, the skin depth becomes small, and the area above the upper electrode cannot be seen from the plasma side, so that the layout of this area devised is useless. On the other hand, when an RF generator for creating plasmas is connected to the lower electrode (e.g., in the case of etching processing in which two different RF generators are connected to a lower electrode), radio-frequency waves propagate in the processing space from the lower electrode to the upper electrode, so that the above-described tendency is small. In this case, even if the resistivity of the electrode plate is made low, no problems occur, and there can be obtained the profound effect of suppressing the occurrence of drift in the electron density of the plasma.

Further, if the etching system 2 is made so that DC voltage can be applied to the upper electrode 4 during plasma processing, as mentioned previously, there can be obtained the following effect. Depending on process, for example, for etching an organic film masked with an inorganic film, plasma with high electron density and low ion energy is required. Although it is easy to create such plasma if an RF generator generating about 100 MHz, for example, is used as the RF generator for creating plasmas, the use of such an RF generator makes the whole system large. It is therefore desirable to use an RF generator that generates a lowest possible frequency.

However, in the case where the frequency is low, if the power is increased in order to obtain high electron density, the ion energy also increases. In such a case, the use of the above-described DC voltage makes it possible to increase the electron density of the plasma while suppressing the energy of ions that are implanted in the wafer W during plasma processing, such as etching processing. It is thus possible to increase the rate of etching a film to be etched, formed on the wafer W, and, at the same time, decrease the rate of sputtering a film formed as a mask on the film to be etched.

Further, by applying DC voltage to the upper electrode 4, it is possible to minimize the damage of the inner wall of the processing chamber 21 to be caused by the ions. The details of this effect are as follows. In a processing system of the type that two RF generators generating different frequencies are connected to a lower electrode, the difference in potential between the plasma and the inner wall of the processing chamber is determined by the sum of the RF amplitude of the higher frequency wave and that of the lower frequency wave. Recently, low-frequency waves, covering from the extremely low power region to the high power region, are widely used in one chamber (processing chamber). Consequently, under the process conditions that only high-frequency waves are used, or that the superimposed power of low-frequency waves is small, the potential to be exerted to the gap between the plasma and the inner wall of the processing chamber is extremely low; while under the process conditions that the power of low-frequency waves is great, the potential to be exerted to the above-described gap is extremely high.

Under the process conditions that by-products of etching are easily deposited on the inner wall of a chamber, if the potential of the inner wall of the chamber is low, the by-products are deposited on the inner wall in an increased amount, and mass-productivity gets worse because of memory effect and the necessity to clean the inner wall. On the contrary, under the process conditions that by-products of etching are not deposited on the inner wall of a chamber easily, if the potential of the inner wall of the chamber is made high, excessively large sputtering force is exerted on the inner wall, which leads to the wear of the parts and the production of particles. In order to balance the above two process conditions, it is necessary to devise chamber dimensions, such as anode/cathode ratio, to make the potential of the inner wall of the chamber appropriate. It is, however, difficult to fulfill all of the requirements.

However, as the following Examples show, the energy to be exerted to the sidewall of the processing chamber 21 in the above-described etching system 2 lowers as the DC voltage to be applied to the upper electrode 4 increases; and when a DC voltage of 50V or more is applied to the upper electrode 4, no energy is exerted to the sidewall of the processing chamber 21. Since the energy to be exerted to the sidewall depends only on the radio-frequency power with a lower frequency, it is possible to decrease the energy to be exerted to the inner wall of the processing chamber 21 in this etching system 2 by about 50 to 100 eV, for example, and thus to protect the inner wall from being sputtered.

### EXAMPLES

The following experiments were carried out in order to confirm the effects of the present invention.

### Example 1

In an etching system having almost the same structure as that of the above-described etching system 2, a wafer W was subjected to etching processing. The change in the electron density of the plasma with time during processing was observed at three different points in the plasma processing space. The three points are 0 mm, 40 mm, and 80 mm apart from the center of the wafer W.

A top plate with a specific resistance value of 75 Ωcm was used in Example 1-1, and a top plate with a specific resistance value of 2 Ωcm, in Example 1-2. The position of each top plate was adjusted so that the distance between the top plate and the wafer W placed on the electrostatic chuck was 25 mm. In this Example 1 (1-1, 1-2), no DC voltage was applied to the upper electrode 4.

To the processing chamber 21, C₅F₈ gas, Ar gas, and O₂ gas were supplied at flow rates of 15 sccm, 380 sccm, and 19 sccm, respectively. The inner pressure of the processing chamber 21 was set to 15 mT. The electric power of the first RF generator 62 and that of the second RF generator 64 were set to 2170 W and 15500 W, respectively.

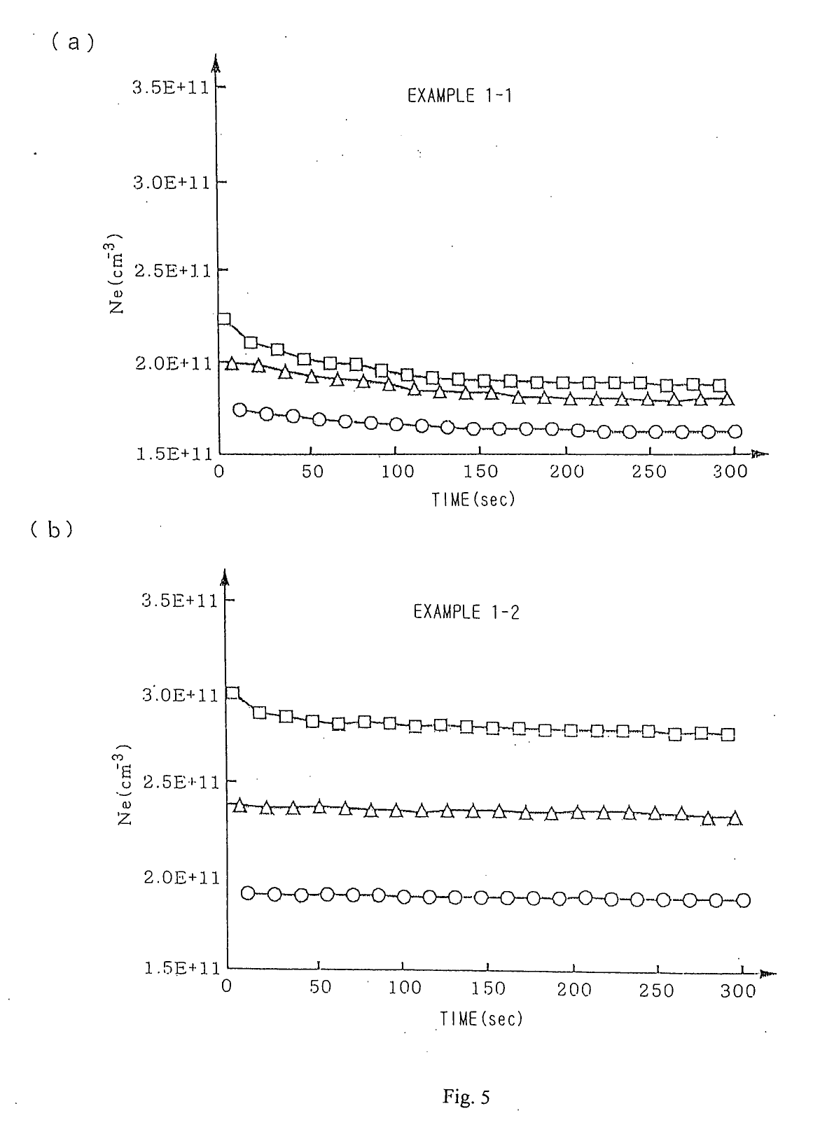

FIG. 5A is a graph showing the results of Example 1-1, and FIG. 5B, a graph showing the results of Example 1-2. In each graph, the electron density of the plasma is plotted vertically, and the time elapsed, horizontally. Further, in the graphs, the square mark corresponds to the measurement point 0 mm apart from the center of the wafer W, the triangular mark, the measurement point 40 mm apart from the center of the wafer W, and the circular mark, the measurement point 80 mm apart from the center of the wafer W.

In Examples 1-1 and 1-2, the electron density of the plasma at the three different points continued to change for a certain period after starting processing and became constant after this period, as shown in FIGS. 5A and 5B. The changes in the electron density of the plasma observed in Example 1-2 were smaller than those changes observed in Example 1-1.

The results of these experiments demonstrate that a wafer W can be uniformly processed when the specific resistance of the top plate is 2 Ωcm. The reason for this seems that only a little drift occurs in the electron density of the plasma, as mentioned previously.

It is clear that occurrence of drift in the electron density of the plasma further reduces if the specific resistance of the top plate is decreased to 1 mΩcm or less. In this case, wafer-to-wafer uniformity in processing can be attained even at the beginning of processing of a new lot of wafers.

### Example 2

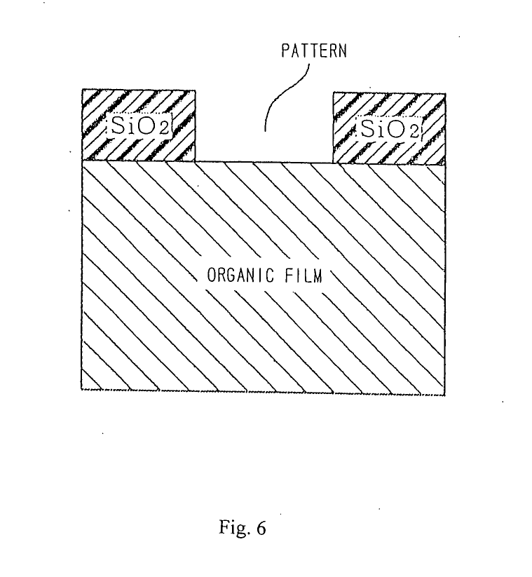

By the use of the above-described etching system 2, etching processing of a wafer W was conducted. The frequencies to be generated by the first and second RF generators were set to 40 MHz and 2 MHz, respectively. On the surface of the Si-made wafer W to be processed, an organic film (resist film) was formed as shown in FIG. 6. On this organic film was further formed a patterned SiO₂ film.

### Example 2-1

The above-described wafer W was subjected to etching processing of Step 1 and then to that of Step 2 under the following processing conditions.

(Step 1)
Inner Pressure of Processing Chamber 21: 50 mT (0.65 ×10 Pa)
Electric Power of First RF Generator 62: 2100 W
Electric Power of Second RF Generator 64: 500 W
Flow Rate of C₄F₈ Gas: 6 sccm
Flow Rate of Ar Gas: 1000 sccm
Flow Rate of N₂ Gas: 150 sccm
Processing Time: 90 seconds

A polymer originating from the activated species of C₄F₈ was deposited on the SiO₂ film surface in the processing of Step 1.

(Step 2)
Inner Pressure of Processing Chamber 21: 10 mT (0.13 ×10 Pa)
Electric Power of First RF Generator 62: 500 W
Electric Power of Second RF Generator 64: 0 W
Flow Rate of O₂ Gas: 200 sccm
DC Voltage of DC Power Supply 52: 0 V
Processing Time: 2 minutes

### Example 2-2

The wafer W was subjected to etching processing of the above-described Step 1 and Step 2, provided that the DC voltage of the DC power supply was set to 300 V.

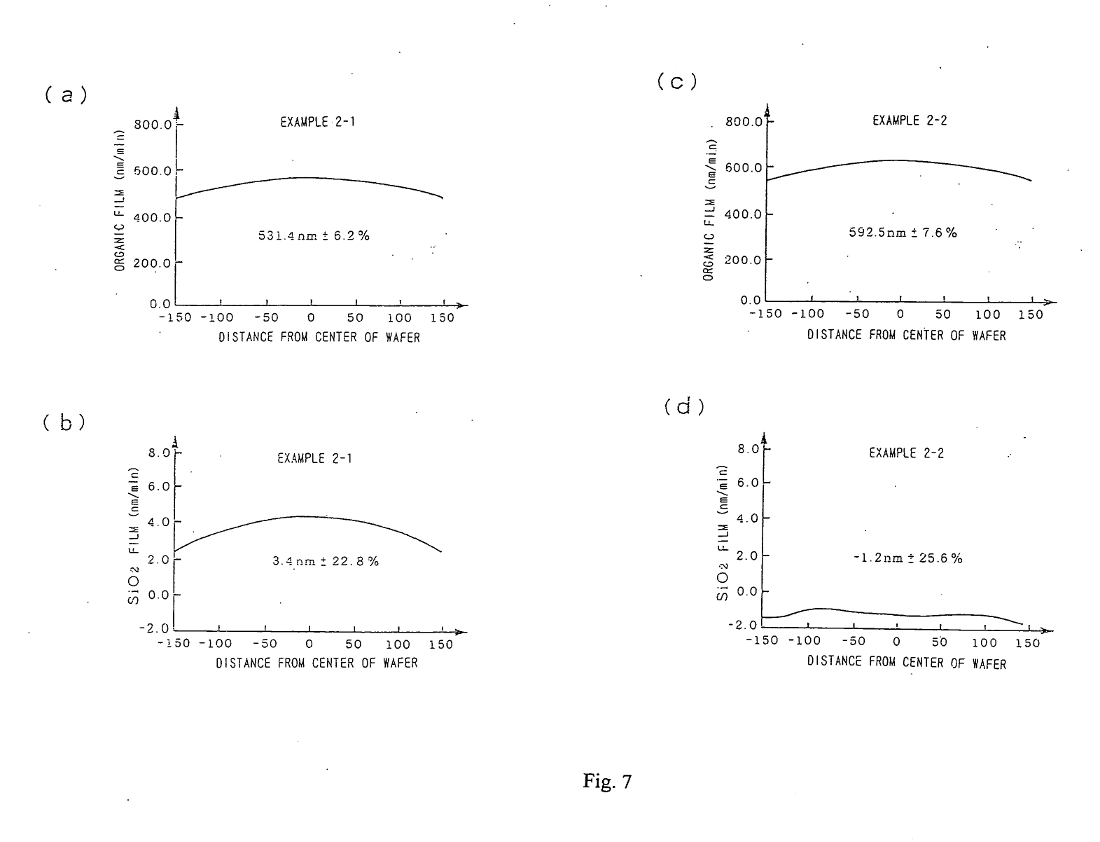

FIG. 7A shows how the etching of the resist film proceeded in Example 2-1, and FIG. 7B, how the etching of the SiO₂ film proceeded in Example 2-1. FIG. 7C shows how the etching of the organic film proceeded in Example 2-2, and FIG. 7D, how the etching of the SiO₂film proceeded in Example 2-2. In each graph, the rate of etching (nm/min) each film is plotted vertically, and the distance from the center of the wafer W, horizontally.

These graphs show that the rate of etching the organic film in Example 2-2 is higher than that in Example 2-1. They also show that the rate of etching the SiO₂ film in Example 2-2 is lower than that in Example 2-1. These results demonstrate that when DC voltage is applied to the upper electrode 4, the electron density of the plasma increases and shifts to the side that the bias on the wafer W is lower.

### Example 3

By the use of the above-described etching system 2, wafers W were processed with the voltage of the DC power supply 52 varied. The energy exerted, during processing, on the sidewall of the processing chamber 21 (wall potential) was measured.

The electric power of the second RF generator 64 was set to 0 W (Example 3-1), to 1000 W (Example 3-2) or to 1500 W (Example 3-3). Other processing conditions were set as follows:
Inner Pressure of Processing Chamber 21: 30 mT (0.39 ×10 Pa)
Electric Power of First RF Generator 62: 1000 W
Flow Rate of C₄F₆ Gas: 30 sccm
Flow Rate of C₄F₈ Gas: 15 sccm
Flow Rate of Ar Gas: 450 sccm
Flow Rate of O₂ Gas: 50 sccm

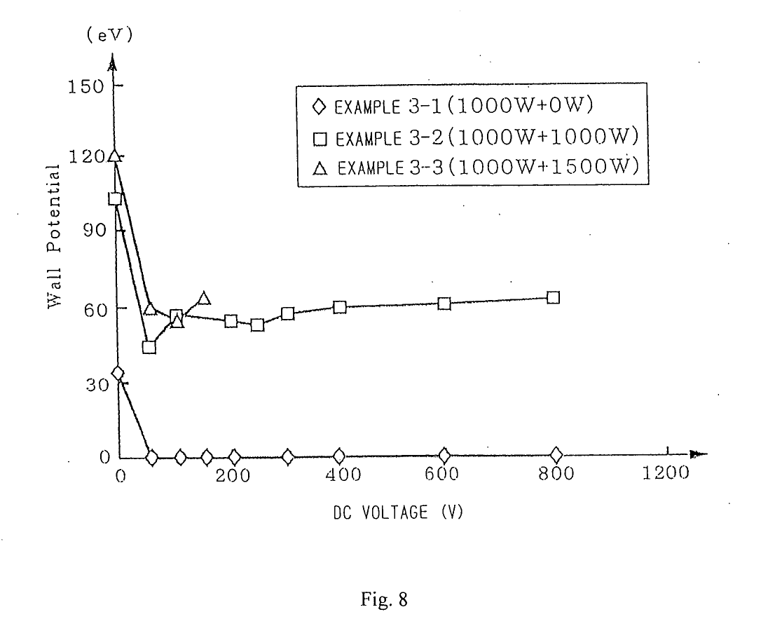

FIG. 8 is a graph showing the results of Example 3 (Examples 3-1 to 3-3). In the graph, the energy exerted on the sidewall of the processing chamber 21 (wall potential) is plotted vertically, and the voltage of the DC power supply 52, horizontally. This graph shows that although the energy exerted to the sidewall of the processing chamber 21 sharply drops while the DC voltage is raised to about 50 V, it remains almost constant when a DC voltage of more than 50 V is applied. Further, at a DC voltage of more than 50 V, the energy exerted on the sidewall of the processing chamber 21 measured in Example 3-2 and that measured in Example 3-3 were almost the same, and that measured in Example 3-1 was nearly zero. From these results, it can be said that only the energy from the first or second RF generator that generates a lower frequency is exerted on the sidewall of the processing chamber 21.

Therefore, by applying DC voltage to the upper electrode 4, it is possible to decrease the energy to be exerted to the sidewall of the processing chamber 21, thereby suppressing sidewall damage. Further, as long as the DC voltage to be applied is as low as about 50 V, it never affects the process greatly, so that it is not necessary to worry about the adverse effect of the application of DC voltage to the upper electrode 4.

1. An electrode plate for use in plasma processing, to be placed in a plasma processing system so that it faces to a substrate to be subjected to plasma processing,
wherein
resistivity of the electrode plate is in a range of 0.01 mΩcm to 2 Ωcm.

2. The electrode plate for use in plasma processing according to claim 1, wherein
the resistivity of the electrode plate is in a range of 0.01 to 1 mΩcm.

3. The electrode plate for use in plasma processing according to claim 1, wherein
the electrode plate is made up of Si or SiC doped with p- or n-type impurities.

4. The electrode plate for use in plasma processing according to claim 2, wherein
the electrode plate is made up of Si or SiC doped with p- or n-type impurities.

5. A plasma processing system comprising:
a processing vessel containing a lower electrode on which a substrate will be placed,
an RF generator for generating plasma, connected to the lower electrode,
an upper electrode having an electrode plate, placed so that it faces to the lower electrode and that it is exposed to a processing atmosphere,
a process-gas supply unit for supplying a process gas to the processing vessel, and
a gas-discharging unit for evacuating the processing vessel to produce a vacuum,
wherein
the resistivity of the electrode plate is in a range of 0.01 mΩcm to 2 Ωcm.

6. The plasma processing system according to claim 5, wherein
DC voltage is adapted to be applied to the electrode plate of the upper electrode.

7. The plasma processing system according to claim 5, wherein
the resistivity of the electrode plate is in a range of 0.01 to 1 mΩcm.

8. The plasma processing system according to claim 6, wherein
the resistivity of the electrode plate is in a range of 0.01 to 1 mΩcm.

9. The plasma processing system according to claim 5, wherein
the electrode plate is made up of Si or SiC doped with p- or n-type impurities.

10. The plasma processing system according to claim 6, wherein
the electrode plate is made up of Si or SiC doped with p- or n-type impurities.

11. The plasma processing system according to claim 7, wherein
the electrode plate is made up of Si or SiC doped with p- or n-type impurities.

12. The plasma processing system according to claim 8, wherein
the electrode plate is made up of Si or SiC doped with p- or n-type impurities.
